(19) United States
(12) Patent Application Publication
(10) Pub. No.: US 2026/0331208 A1
(43) Pub. Date: Oct. 22, 2026

(54) MEMORY DEVICE FOR DETECTING FAULT IN SIGNAL PATHS AND VOLTAGE PATHS

(71) Applicant: SK hynix Inc., Icheon-si Gyeonggi-do (KR)

(72) Inventors: Min Kyu MOON, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 19/297,943

(22) Filed: Aug. 12, 2025

(30) Foreign Application Priority Data
Apr. 16, 2025 (KR) 10-2025-0049810

(51) Int. Cl. G11C 29/50; H01L 25/065; H01L 25/18; H10B 80/00

(52) U.S. Cl. CPC G11C 29/50; H10B 80/00; H10W 90/00; G11C 2029/5004; H10W 90/297; H10W 90/722; H10W 90/724

(57) ABSTRACT

A memory device includes a base chip and a core chip, the core chip stacked over the base chip and connected through a voltage path. The base chip and the core chip drive the voltage path with an internal voltage after a start of a TSV open short test and detect a connection fail of the voltage path based on a logic level at which the voltage path is driven. The base chip cuts off the connection between the voltage path and a base driving circuit after a start of a voltage monitoring operation. The core chip cuts off the connection between the voltage path and a core driving circuit after the start of the voltage monitoring operation. The base chip detects a voltage level of a monitoring voltage, generated during the voltage monitoring operation, that is used in the core chip through the voltage path.

### CROSS-REFERENCE TO RELATED APPLICATION

The present application claims priority under 35 U.S.C. § 119(a) to Korean Patent Application No. 10-2025-0049810, filed in the Korean Intellectual Property Office on Apr. 16, 2025, the entire contents of which application is incorporated herein by reference.

### BACKGROUND

The present disclosure relates to a memory device for detecting a fault in signal paths for stacking a plurality of chips and voltage paths for voltage monitoring.

As a technology for manufacturing a memory device advances, a packaging technology for a plurality of core chips for implementing the memory device accomplishes high integration and high performance. In packaging technologies for implementing the memory device, a technology relating to a three-dimensional structure in which a plurality of core chips is vertically stacked from a two-dimensional structure in which a plurality of core chips is flatly disposed on a printed circuit board (PCB) is variously developed. The memory device having the three-dimensional structure may be implemented by stacking a plurality of core chips that are interconnected through a through silicon via (hereinafter referred to as a “TSV”), for example, a high bandwidth memory (HBM), or may be implemented by stacking a plurality of core chips through wire bonding.

In accordance with higher integration and higher performance, methods for detecting a connection fail in TSVs when stacking a plurality of core chips are required. A representative method for detecting a connection fail in TSVs may be performed through a TSV open short test by turning on a PMOS transistor connected to the TSV of a core chip disposed at the top layer, turning on an NMOS transistor connected to the TSV of a base chip disposed at the bottom, and then detecting that the TSV is driven to a set logic level.

### SUMMARY

In an embodiment, a memory device may include a base chip and a core chip, the core chip stacked over the base chip and connected through a voltage path. The base chip and the core chip may drive the voltage path with an internal voltage after the start of a TSV open short test and detect a connection fail of the voltage path based on a logic level at which the voltage path is driven. The base chip may cut off the connection between the voltage path and a base driving circuit after the start of a voltage monitoring operation. The core chip may cut off the connection between the voltage path and a core driving circuit after the start of the voltage monitoring operation. The base chip may detect a voltage level of a monitoring voltage, generated during the voltage monitoring operation, that is used in the core chip through the voltage path.

In an embodiment, a memory device may include a base chip and a core chip, the core chip stacked over the based chip and connected through first and second voltage paths. The base chip and the core chip may drive the first and second voltage paths with an internal voltage after the start of a TSV open short test and detect a connection fail of the first and second voltage paths based on logic levels at which the first and second voltage paths are driven. The base chip may detect a voltage level of a monitoring voltage that is generated from any one of a power supply voltage that is received through the first voltage path and a high voltage that is received through the second voltage path after the start of a voltage monitoring operation.

In an embodiment, a memory device may include a base chip and a core chip, the core chip stacked over the base chip and connected through a signal path and a voltage path. The base chip and the core chip may drive the signal path and the voltage path after the start of a TSV open short test and detect a connection fail of the signal path and the voltage path based on logic levels at which the signal path and the voltage path are driven. The base chip may cut off the connection between the voltage path and a base driving circuit after the start of a voltage monitoring operation. The core chip may cut off the connection between the voltage path and the path driving circuit after the start of the voltage monitoring operation. The base chip may detect a voltage level of a high voltage that is used in the core chip through the voltage path after the start of the voltage monitoring operation.

In an embodiment, an integrated circuit may include a semiconductor device configured to drive first and second voltage paths with an internal voltage after the start of a TSV open short test, configured to control the connection between the first and second voltage paths and first and second base driving circuits, configured to detect a connection fail of the first and second voltage paths based on logic levels at which the first and second voltage paths are driven, and configured to detect a voltage level of a monitoring voltage that is generated from any one of a power supply voltage that is received through the first voltage path and a high voltage that is received through the second voltage path after the start of a voltage monitoring operation.

### BRIEF DESCRIPTION OF THE DRAWINGS

FIG. 1 is a block diagram illustrating a construction of a memory system according to an embodiment of the present disclosure.

FIG. 2 is a block diagram illustrating a construction of a memory device according to an embodiment of the present disclosure.

FIG. 3 is a block diagram illustrating a construction of a base chip according to an embodiment of the present disclosure.

FIG. 4 is a block diagram illustrating a construction of a test control circuit according to an embodiment of the present disclosure.

FIG. 5 is a block diagram illustrating a construction of a base test circuit according to an embodiment of the present disclosure.

FIG. 6 is a diagram illustrating a construction of a first fail signal generation circuit according to an embodiment of the present disclosure.

FIG. 7 is a diagram illustrating a construction of a third fail signal generation circuit according to an embodiment of the present disclosure.

FIG. 8 is a diagram illustrating a construction of a fourth fail signal generation circuit according to an embodiment of the present disclosure.

FIG. 9 is a block diagram illustrating a construction of a fourth core chip according to an embodiment of the present disclosure.

FIG. 10 is a block diagram illustrating a construction of a core test circuit according to an embodiment of the present disclosure.

FIG. 11 is a diagram illustrating a construction of a first path driving circuit according to an embodiment of the present disclosure.

FIG. 12 is a diagram illustrating a construction of a third path driving circuit according to an embodiment of the present disclosure.

FIG. 13 is a diagram illustrating a construction of a fourth path driving circuit according to an embodiment of the present disclosure.

FIG. 14 is a block diagram illustrating a construction of a voltage monitoring circuit according to an embodiment of the present disclosure.

FIG. 15 is a table for describing an operation that detects a connection fail of a voltage path and a fail of a monitoring voltage in the memory device according to an embodiment of the present disclosure.

### DETAILED DESCRIPTION

In the descriptions of the following embodiments, terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

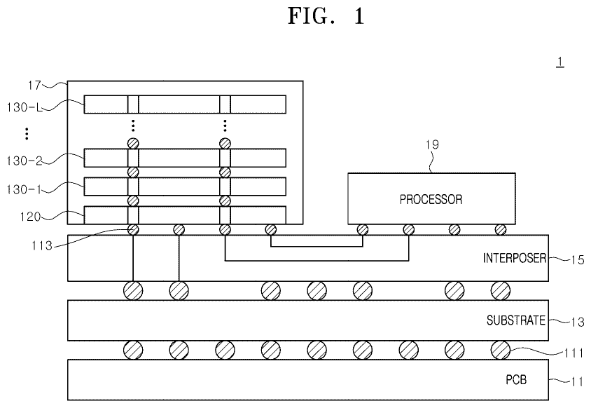

FIG. 1 is a block diagram illustrating a construction of a memory system 1 according to an embodiment of the present disclosure. As illustrated in FIG. 1, the memory system 1 may include a PCB 11, a substrate 13, an interposer 15, a memory device 17, and a processor 19.

The PCB 11 connects several electronic components in order to form an electronic circuit (not illustrated). A copper layer, a solder mask and a silk screen may be formed on the PCB 11. A circuit path that transmits a signal or power may be formed in the copper layer. The solder mask prevents damage to the circuit and protects a specific region in which components may be soldered. Furthermore, the silk screen indicates a position or information of an electronic component in the form of characters or symbols printed on a surface of the PCB 11.

The substrate 13 is formed over the PCB 11 with bump pads (e.g., 111) therebetween and may mechanically support the interposer 15, the memory device 17, and the processor 19. The substrate 13 may be used as an insulator, that is, a physical base for the PCB 11, in general. The material of the substrate 13 includes FR4, that is, an insulator made of glass fiber and epoxy resin, ceramics that can withstand a high temperature and is commonly used in a high frequency circuit or a high temperature environment due to its thermal conductivity, and polyimide that is used as a base material for a flexible PCB due to its flexible characteristic.

The interposer 15 is formed over the substrate 13 through bump pads and may include wires that connect electronic components (e.g., the memory device 17 and the processor 19) with unmatched form factors or pin arrangements. The interposer 15 may convert signals in different interfaces.

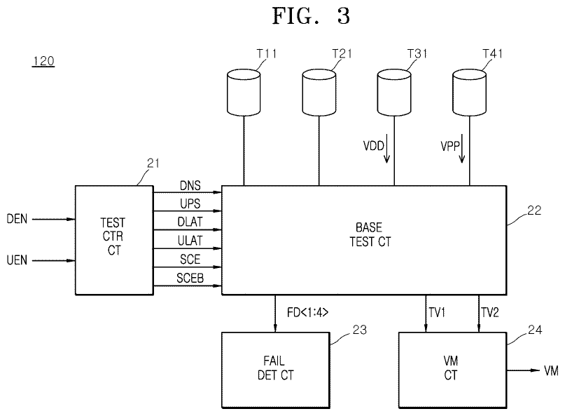

The memory device 17 may be formed over the interposer 15 with micro bump pads (e.g., 113) therebetween. Under the control of the processor 19, the memory device 17 may store data applied by the processor 19 or may output data stored in the memory device 17 to the processor 19. The memory device 17 may include a base chip 120 and a plurality of core chips 130-1 to 130-L. The plurality of core chips 130-1 to 130-L may be stacked on or over the base chip 120 with micro bump pads therebetween. The base chip 120 and the plurality of core chips 130-1 to 130-L may be vertically connected through TSVs. The base chip 120 may drive a signal path after the start of a TSV open short test. The base chip 120 may detect a connection fail of the signal path based on a logic level at which the signal path is driven after the start of a TSV open short test. The base chip 120 may drive a voltage path after the start of a TSV open short test. The base chip 120 may detect a connection fail of the voltage path based on a logic level at which the voltage path is driven after the start of a TSV open short test. The base chip 120 may detect the voltage levels of a power supply voltage (VDD in FIG. 3) and a high voltage (VPP in FIG. 3) that are used in the plurality of core chips 130-1 to 130-L after the start of a voltage monitoring operation. The signal path and the voltage path may each be set as a path along which a TSV and a micro bump pad are connected. The signal path may be set as a path along which signals that are input and output between the base chip 120 and the plurality of core chips 130-1 to 130-L are transmitted. The voltage path may be set as a path for detecting, by the base chip 120, a voltage that is used in the plurality of core chips 130-1 to 130-L.

The base chip 120 may be implemented with a common semiconductor device, controller, or integrated circuit that controls operations of the plurality of core chips 130-1 to 130-L. The plurality of core chips 130-1 to 130-L may each be implemented with a common semiconductor device, common memory device, or integrated circuit that stores data and outputs stored data.

The core chip 130-L disposed at a top layer, among the plurality of core chips 130-1 to 130-L, may drive a signal path after the start of a TSV open short test. Each of the plurality of core chips 130-1 to 130-L may input and output data through each signal paths. Each of the plurality of core chips 130-1 to 130-L may store data and output data stored in each core chip. The core chip 130-L disposed at the top layer, among the plurality of core chips 130-1 to 130-L, may drive a voltage path after the start of a TSV open short test. The plurality of core chips 130-1 to 130-L may output the power supply voltage (VDD in FIG. 3) and the high voltage (VPP in FIG. 3) to the base chip 120 through the voltage path after the start of a voltage monitoring operation.

Each of the plurality of core chips 130-1 to 130-L may include a plurality of channel regions that independently operates. Each of the plurality of channel regions may be assigned a channel that independently operates and may receive and transmit data. The number L of core chips, among the plurality of core chips 130-1 to 130-L, may be 4, 8, 12, or 16. For example, when each of the core chips 130-1 to 130-12 includes 8 channels, each of the core chips 130-1 to 130-4, the core chips 130-5 to 130-8, and the core chips 130-9 to 130-12 may include 32 channel regions and may transmit and receive data to and from the processor 19 in a rank unit including 32 channels.

The processor 19 may detect a signal transmission path in which a fail occurs, among the signal transmission paths of the base chip 120, through a wire formed within the interposer 15.

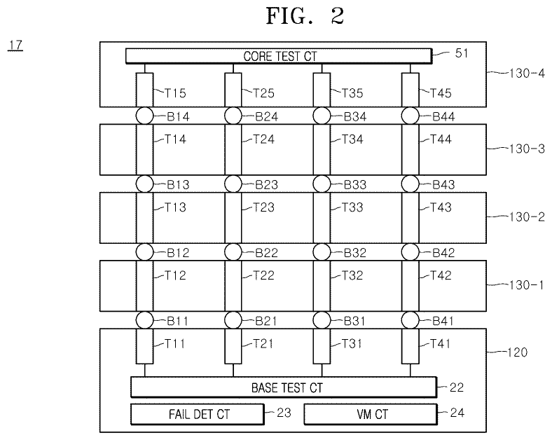

FIG. 2 is a block diagram illustrating a construction of the memory device 17 according to an embodiment of the present disclosure. As illustrated in FIG. 2, the memory device 17 may include the base chip 120, the first core chip 130-1, the second core chip 130-2, the third core chip 130-3, and the fourth core chip 130-4.

The base chip 120 may be electrically connected to first and second signal paths and first and second voltage paths. The first signal path may be implemented by electrically connecting TSVs T11, T12, T13, T14, and T15 and micro bump pads B11, B12, B13, and B14. The second signal path may be implemented by electrically connecting TSVs T21, T22, T23, T24, and T25 and micro bump pads B21, B22, B23, and B24. The first voltage path may be implemented by electrically connecting TSVs T31, T32, T33, T34, and T35 and micro bump pads B31, B32, B33, and B34. The second voltage path may be implemented by electrically connecting TSVs T41, T42, T43, T44, and T45 and micro bump pads B41, B42, B43, and B44. The first and second signal paths may be implemented with paths along which signals that control operations of the first core chip 130-1, the second core chip 130-2, the third core chip 130-3, and the fourth core chip 130-4 are input and output. The first and second voltage paths may be set as paths along which the power supply voltage (VDD in FIG. 3) and the high voltage (VPP in FIG. 3) that are used in the first core chip 130-1, the second core chip 130-2, the third core chip 130-3, and the fourth core chip 130-4 are output.

The TSVs T11, T12, T13, T14, T15, T21, T22, T23, T24, T25, T31, T32, T33, T34, T35, T41, T42, T43, T44, and T45 may be implemented in a cylindrical form by using a conductive material that connects the base chip 120, the first core chip 130-1, the second core chip 130-2, the third core chip 130-3, and the fourth core chip 130-4 to each other when vertically stacked. The micro bump pads B11, B12, B13, B14, B21, B22, B23, B24, B31, B32, B33, B34, B41, B42, B43, and B44 may be implemented in a ball form by using a conductive material in order to be directly connected to a circuit board. The first and second signal paths and the first and second voltage paths are each implemented to include five TSVs but may be implemented to include various numbers of TSVs according to an embodiment.

The base chip 120 may include the TSVs T11, T21, T31, and T41, a base test circuit (BASE TEST CT) 22, a fail detection circuit (FAIL DET CT) 23, and a voltage monitoring circuit (VM CT) 24.

The TSV T11 may be electrically connected to the micro bump pad B11. The TSV T21 may be electrically connected to the micro bump pad B21. The TSV T31 may be electrically connected to the micro bump pad B31. The TSV T41 may be electrically connected to the micro bump pad B41.

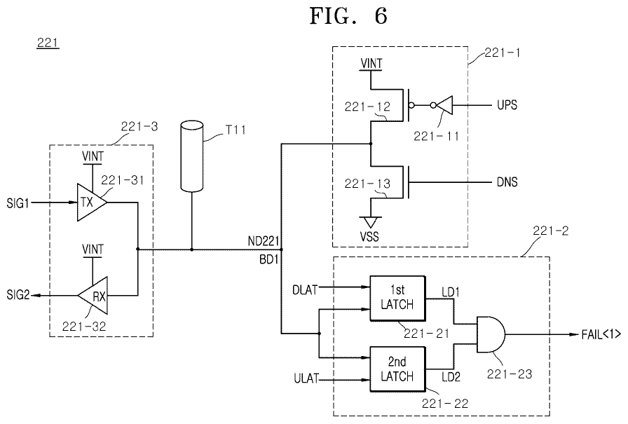

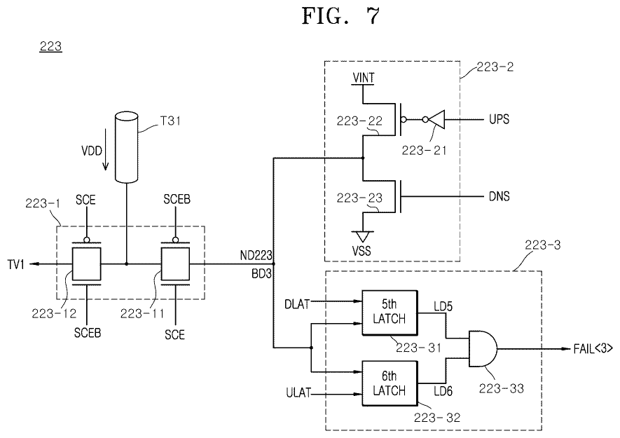

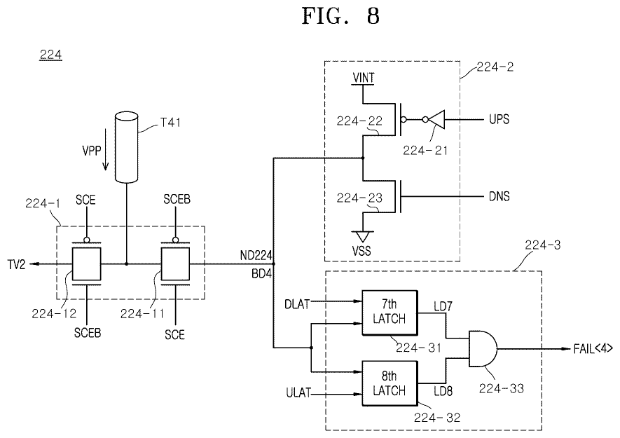

The base test circuit 22 may drive the TSVs T11, T21, T31, and T41 through any one of a PMOS transistor and an NMOS transistor after the start of a TSV open short test. The base test circuit 22 may drive the TSVs T11, T21, T31, and T41 with an internal voltage (VINT in FIG. 6) through the PMOS transistor after the start of an up TSV open short test of a TSV open short test. The base test circuit 22 may drive the TSVs T11, T21, T31, and T41 with a ground voltage (VSS in FIG. 6) through the NMOS transistor after the start of a down TSV open short test of a TSV open short test. The base test circuit 22 may generate first to fourth fail detection signals (FD<1:4> in FIG. 3) by detecting the logic level of an internal node that is connected to the TSVs T11, T21, T31, and T41 after the start of a TSV open short test. The base test circuit 22 may cut off the connection between the TSV T31 of the first voltage path and a third base driving circuit (223-2 in FIG. 7) after the start of a voltage monitoring operation. The base test circuit 22 may cut off the connection between the TSV T41 of the second voltage path and a fourth base driving circuit (224-2 in FIG. 8) after the start of a voltage monitoring operation.

The fail detection circuit 23 may detect a connection fail of the first and second signal paths and the first and second voltage paths based on the first to fourth fail detection signals (FD<1:4> in FIG. 3) after the start of a TSV open short test.

The voltage monitoring circuit 24 may detect the voltage levels of the power supply voltage (VDD in FIG. 3) that is input through the first voltage path and the high voltage (VPP in FIG. 3) that is input through the second voltage path.

The first core chip 130-1 may be electrically connected to the micro bumps B11, B21, B31, and B41 and may be stacked on the base chip 120.

The first core chip 130-1 may include the TSVs T12, T22, T32, and T42.

The TSV T12 may be electrically connected between the micro bump pad B11 and the micro bump pad B12. The TSV T22 may be electrically connected between the micro bump pad B21 and the micro bump pad B22. The TSV T32 may be electrically connected between the micro bump pad B31 and the micro bump pad B32. The TSV T42 may be electrically connected between the micro bump pad B41 and the micro bump pad B42.

The second core chip 130-2 may be electrically connected to the micro bump pads B12, B22, B32, and B42 and may be stacked on the first core chip 130-1.

The second core chip 130-2 may include the TSVs T13, T23, T33, and T43.

The TSV T13 may be electrically connected between the micro bump pad B12 and the micro bump pad B13. The TSV T23 may be electrically connected between the micro bump pad B22 and the micro bump pad B23. The TSV T33 may be electrically connected between the micro bump pad B32 and the micro bump pad B33. The TSV T43 may be electrically connected between the micro bump pad B42 and the micro bump pad B43.

The third core chip 130-3 may be electrically connected to the micro bump pads B13, B23, B33, and B43 and may be stacked on the second core chip 130-2.

The third core chip 130-3 may include the TSVs T14, T24, T34, and T44.

The TSV T14 may be electrically connected between the micro bump pad B13 and the micro bump pad B14. The TSV T24 may be electrically connected between the micro bump pad B23 and the micro bump pad B24. The TSV T34 may be electrically connected between the micro bump pad B33 and the micro bump pad B34. The TSV T44 may be electrically connected between the micro bump pad B43 and the micro bump pad B44.

The fourth core chip 130-4 may be electrically connected to the micro bump pads B14, B24, B34, and B44 and may be stacked on the third core chip 130-3.

The fourth core chip 130-4 may include the TSVs T15, T25, T35, and T45 and a core test circuit (CORE TEST CT) 51.

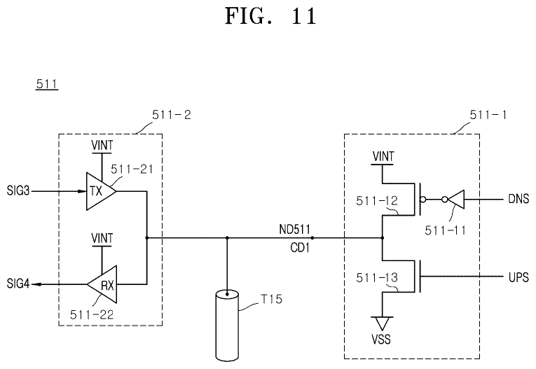

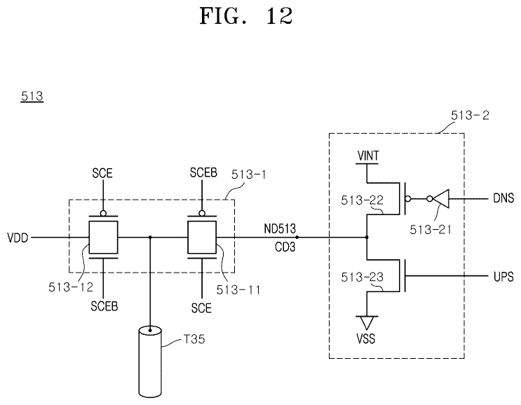

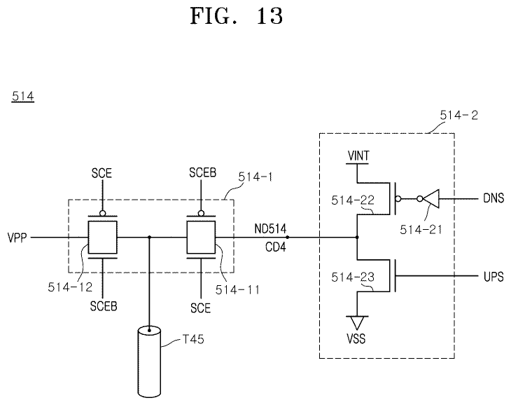

The core test circuit 51 may drive the TSVs T15, T25, T35, and T45 through any one of a PMOS transistor and an NMOS transistor after the start of a TSV open short test. The core test circuit 51 may drive the TSVs T15, T25, T35, and T45 with an internal voltage (VINT in FIG. 11) through the PMOS transistor after the start of a down TSV open short test of a TSV open short test. The core test circuit 51 may drive the TSVs T15, T25, T35, and T45 with a ground voltage (VSS in FIG. 11) through the NMOS transistor after the start of an up TSV open short test of a TSV open short test. The core test circuit 51 may cut off the connection between the TSV T35 of the first voltage path and a third core driving circuit (513-2 in FIG. 12) after the start of a voltage monitoring operation. The core test circuit 51 may cut off the connection between the TSV T45 of the second voltage path and a fourth core driving circuit (514-2 in FIG. 13) after the start of a voltage monitoring operation.

In FIG. 2, the first core chip 130-1, the second core chip 130-2, the third core chip 130-3, and the fourth core chip 130-4 are vertically stacked on the base chip 120, but various numbers of core chips, for example, 8 and 16, may be stacked on the base chip 120 according to embodiments.

The memory device 17, illustrated in FIG. 2, is implemented by vertically stacking the base chip 120, the first core chip 130-1, the second core chip 130-2, the third core chip 130-3, and the fourth core chip 130-4, interconnected through TSVs, like a high bandwidth memory (HBM), but the disclosure is not limited thereto and may be implemented so that a plurality of core chips is stacked through wire bonding according to an embodiment.

FIG. 3 is a block diagram illustrating a construction of the base chip 120 according to an embodiment of the present disclosure. The base chip 120 may include a test control circuit (TEST CTR CT) 21, the base test circuit 22, the fail detection circuit 23, and the voltage monitoring circuit 24.

Based on a down scan enable signal DEN and an up scan enable signal UEN, the test control circuit 21 may generate a down scan signal DNS, an up scan signal UPS, a down latch signal DLAT, and an up latch signal ULAT. The down scan enable signal DEN may be set as a signal that is enabled after the start of a down TSV open short test of a TSV open short test. The up scan enable signal UEN may be set as a signal that is enabled after the start of an up TSV open short test of a TSV open short test. The test control circuit 21 may generate the down scan signal DNS that is enabled when the down scan enable signal DEN is enabled. The test control circuit 21 may generate the down latch signal DLAT by delaying the down scan signal DNS. The test control circuit 21 may generate the up scan signal UPS that is enabled when the up scan enable signal UEN is enabled. The test control circuit 21 may generate the up latch signal ULAT by delaying the up scan signal UPS.

Based on the down scan enable signal DEN and the up scan enable signal UEN, the test control circuit 21 may generate a scan enable signal SCE and an inverse scan enable signal SCEB. The test control circuit 21 may generate the scan enable signal SCE that is enabled to the voltage level of the high voltage VPP when any one of the down scan enable signal DEN and the up scan enable signal UEN is enabled. The test control circuit 21 may generate the inverse scan enable signal SCEB that is enabled to the voltage level of the high voltage VPP when both the down scan enable signal DEN and the up scan enable signal UEN are disabled.

The base test circuit 22 may be electrically connected to the TSVs T11, T21, T31, and T41. The base test circuit 22 may drive the TSVs T11, T21, T31, and T41 through any one of the PMOS transistor and the NMOS transistor after the start of a TSV open short test. The base test circuit 22 may drive the TSVs T11, T21, T31, and T41 through any one of the PMOS transistor and the NMOS transistor based on the down scan signal DNS and the up scan signal UPS after the start of a TSV open short test. The base test circuit 22 may latch the logic level of an internal node that is connected to the TSVs T11, T21, T31, and T41 based on the down latch signal DLAT and the up latch signal ULAT after the start of a TSV open short test. The base test circuit 22 may generate the first to fourth fail detection signals FD<1:4> by detecting the logic level of the internal node that is connected to the TSVs T11, T21, T31, and T41 that have been latched after the start of a TSV open short test.

The base test circuit 22 may output, as a first transfer voltage TV1, the power supply voltage VDD that is transferred through the TSV T31 of the first voltage path based on the scan enable signal SCE and the inverse scan enable signal SCEB after the start of a voltage monitoring operation. The base test circuit 22 may output, as a second transfer voltage TV2, the high voltage VPP that is transferred through the TSV T41 of the second voltage path based on the scan enable signal SCE and the inverse scan enable signal SCEB after the start of a voltage monitoring operation. The base test circuit 22 may cut off the connection between the TSV T31 of the first voltage path and the third base driving circuit (223-2 in FIG. 7) based on the scan enable signal SCE and the inverse scan enable signal SCEB after the start of a voltage monitoring operation. The base test circuit 22 may cut off the connection between the TSV T41 of the second voltage path and the fourth base driving circuit (224-2 in FIG. 8) based on the scan enable signal SCE and the inverse scan enable signal SCEB after the start of a voltage monitoring operation. The power supply voltage VDD may be set as a voltage having a higher voltage level than the internal voltage (VINT in FIG. 6). The high voltage VPP may be set as a voltage having a higher voltage level than the power supply voltage VDD. The internal voltage (VINT in FIG. 6) is a voltage that is used within the first to fourth core chips 130-1 to 130-4 and may be set as a voltage that is generated by reducing the voltage level of the power supply voltage VDD.

An operation that cuts off, by the base test circuit 22, the connection between the TSV T31 of the first voltage path and the third base driving circuit (223-2 in FIG. 7) after the start of a voltage monitoring operation is intended to protect elements included in the third base driving circuit (223-2 in FIG. 7) when the power supply voltage VDD having a high voltage level is output to the first voltage path. An operation that cuts off, by the base test circuit 22, the connection between the TSV T41 of the second voltage path and the fourth base driving circuit (224-2 in FIG. 8) after the start of a voltage monitoring operation is intended to protect elements included in the fourth base driving circuit (224-2 in FIG. 8) when the high voltage VPP having a high voltage level is output to the third voltage path.

The fail detection circuit 23 may detect a connection fail of the first and second signal paths and the first and second voltage paths based on the first to fourth fail detection signals FD<1:4> after the start of a TSV open short test. The fail detection circuit 23 may detect an open fail in which the first and second signal paths and the first and second voltage paths are disconnected by detecting the logic levels of the first to fourth fail detection signals FD<1:4> after the start of a TSV open short test. The fail detection circuit 23 may detect a short fail in which the first and second signal paths and the first and second voltage paths are connected by detecting the logic levels of the first to fourth fail detection signals FD<1:4> after the start of a TSV open short test.

The voltage monitoring circuit 24 may receive the first transfer voltage TV1 and the second transfer voltage TV2 after the start of a voltage monitoring operation. The voltage monitoring circuit 24 may generate a monitoring voltage VM from any one of the first transfer voltage TV1 and the second transfer voltage TV2 after the start of a voltage monitoring operation. The voltage monitoring circuit 24 may detect the voltage level of the monitoring voltage VM after the start of a voltage monitoring operation. The voltage monitoring circuit 24 may output the monitoring voltage VM to an external device, for example, the processor 19 after the start of a voltage monitoring operation.

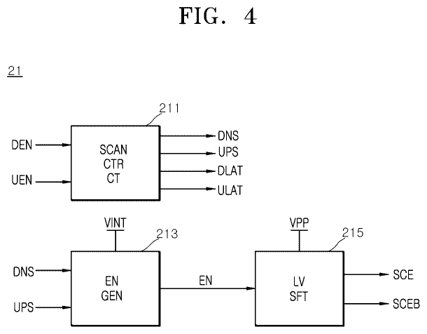

FIG. 4 is a block diagram illustrating a construction of the test control circuit 21 according to an embodiment of the present disclosure. The test control circuit 21 may include a scan control circuit (SCAN CTR CT) 211, an enable signal generation circuit (EN GEN) 213, and a level shifting circuit (LV SFT) 215.

Based on the down scan enable signal DEN and the up scan enable signal UEN, the scan control circuit 211 may generate the down scan signal DNS, the up scan signal UPS, the down latch signal DLAT, and the up latch signal ULAT. The scan control circuit 211 may generate the down scan signal DNS that is enabled when the down scan enable signal DEN is enabled. The scan control circuit 211 may generate the up scan signal UPS that is enabled when the up scan enable signal UEN is enabled. The scan control circuit 211 may generate the down latch signal DLAT by delaying the down scan signal DNS. The scan control circuit 211 may generate the up latch signal ULAT by delaying the up scan signal UPS.

The enable signal generation circuit 213 may receive the internal voltage VINT and may generate an enable signal EN based on the down scan signal DNS and the up scan signal UPS. The enable signal generation circuit 213 may generate the enable signal EN that is driven to the voltage level of the internal voltage VINT when any one of the down scan signal DNS and the up scan signal UPS is enabled.

The level shifting circuit 215 may receive the high voltage VPP and may generate the scan enable signal SCE and the inverse scan enable signal SCEB by converting the logic level of the enable signal EN. When the enable signal EN is enabled, the level shifting circuit 215 may generate the scan enable signal SCE having the voltage level of the high voltage VPP and the inverse scan enable signal SCEB having the voltage level of the ground voltage VSS. When the enable signal EN is disabled, the level shifting circuit 215 may generate the inverse scan enable signal SCEB having the voltage level of the high voltage VPP and the scan enable signal SCE having the voltage level of the ground voltage VSS. The level shifting circuit 215 may be implemented with a common level shifting circuit.

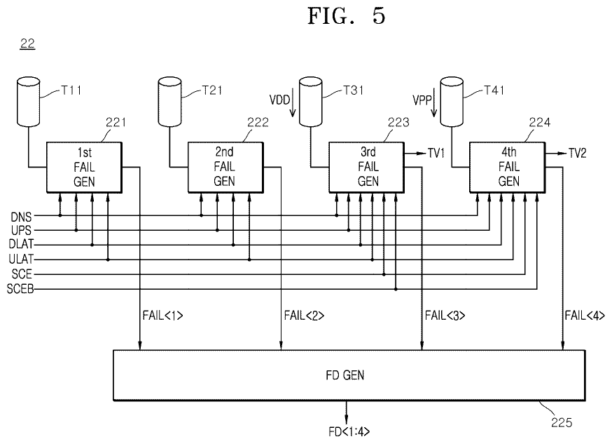

FIG. 5 is a block diagram illustrating a construction of the base test circuit 22 according to an embodiment of the present disclosure. The base test circuit 22 may include a first fail signal generation circuit (1^{st} FAIL GEN) 221, a second fail signal generation circuit (2^{nd} FAIL GEN) 222, a third fail signal generation circuit (3^{rd} FAIL GEN) 223, a fourth fail signal generation circuit (4^{th} FAIL GEN) 224, and a fail detection signal generation circuit (FD GEN) 225.

The first fail signal generation circuit 221 may be electrically connected to the TSV T11 of the first signal path. The first fail signal generation circuit 221 may generate a first fail signal FAIL<1> based on the down scan signal DNS, the up scan signal UPS, the down latch signal DLAT, and the up latch signal ULAT. The first fail signal generation circuit 221 may drive the TSV T11 through an NMOS transistor (221-13 in FIG. 6) when the down scan signal DNS is enabled after the start of a down TSV open short test. The first fail signal generation circuit 221 may latch the logic level of an internal node (ND221 in FIG. 6) that is connected to the TSV T11 driven through an AND gate (221-23 in FIG. 6) when the down latch signal DLAT is enabled after the start of a down TSV open short test. The first fail signal generation circuit 221 may drive the TSV T11 through a PMOS transistor (221-12 in FIG. 6) when the up scan signal UPS is enabled after the start of an up TSV open short test. The first fail signal generation circuit 221 may latch the logic level of the internal node (ND221 in FIG. 6) that is connected to the TSV T11 driven through the PMOS transistor (221-12 in FIG. 6) when the up latch signal ULAT is enabled after the start of an up TSV open short test. The first fail signal generation circuit 221 may generate the first fail signal FAIL<1> based on the logic level of the internal node (ND221 in FIG. 6) that is connected to the TSV T11.

The second fail signal generation circuit 222 may be electrically connected to the TSV T21 of the second signal path. The second fail signal generation circuit 222 may generate a second fail signal FAIL<2> based on the down scan signal DNS, the up scan signal UPS, the down latch signal DLAT, and the up latch signal ULAT. The second fail signal generation circuit 222 may drive the TSV T21 through an NMOS transistor (not illustrated) when the down scan signal DNS is enabled after the start of a down TSV open short test. The second fail signal generation circuit 222 may latch the logic level of an internal node (not illustrated) that is connected to the TSV T21 driven through the NMOS transistor (not illustrated) when the down latch signal DLAT is enabled after the start of a down TSV open short test. The second fail signal generation circuit 222 may drive the TSV T21 through a PMOS transistor (not illustrated) when the up scan signal UPS is enabled after the start of an up TSV open short test. The second fail signal generation circuit 222 may latch the logic level of the internal node (not illustrated) that is connected to the TSV T21 driven through a PMOS transistor (not illustrated) when the up latch signal ULAT is enabled after the start of an up TSV open short test. The second fail signal generation circuit 222 may generate the second fail signal FAIL<2> based on the logic level of the internal node (not illustrated) that is connected to the TSV T21.

The third fail signal generation circuit 223 may be electrically connected to the TSV T31 of the first voltage path. The third fail signal generation circuit 223 may generate a third fail signal FAIL<3> based on the down scan signal DNS, the up scan signal UPS, the down latch signal DLAT, and the up latch signal ULAT. The third fail signal generation circuit 223 may drive the TSV T31 through an NMOS transistor (223-23 in FIG. 7) when the down scan signal DNS is enabled after the start of a down TSV open short test. The third fail signal generation circuit 223 may latch the logic level of an internal node (ND223 in FIG. 7) that is connected to the TSV T31 driven through the NMOS transistor (223-23 in FIG. 7) when the down latch signal DLAT is enabled after the start of a down TSV open short test. The third fail signal generation circuit 223 may drive the TSV T31 through a PMOS transistor (223-22 in FIG. 7) when the up scan signal UPS is enabled after the start of an up TSV open short test. The third fail signal generation circuit 223 may latch the logic level of the internal node (ND223 in FIG. 7) that is connected to the TSV T31 driven through the PMOS transistor (223-22 in FIG. 7) when the up latch signal ULAT is enabled after the start of an up TSV open short test. The third fail signal generation circuit 223 may generate the third fail signal FAIL<3> based on the logic level of the internal node (ND223 in FIG. 7) that is connected to the TSV T31. The third fail signal generation circuit 223 may receive a power supply voltage VDD through the TSV T31 of the first voltage path after the start of a voltage monitoring operation. The third fail signal generation circuit 223 may output the power supply voltage VDD as the first transfer voltage TV1 after the start of a voltage monitoring operation.

The fourth fail signal generation circuit 224 may be electrically connected to the TSV T41 of the second voltage path. The fourth fail signal generation circuit 224 may generate a fourth fail signal FAIL<4> based on the down scan signal DNS, the up scan signal UPS, the down latch signal DLAT, and the up latch signal ULAT. The fourth fail signal generation circuit 224 may drive the TSV T41 through an NMOS transistor (224-23 in FIG. 8) when the down scan signal DNS is enabled after the start of a down TSV open short test. The fourth fail signal generation circuit 224 may latch the logic level of an internal node (ND224 in FIG. 8) that is connected to the TSV T41 driven through the NMOS transistor (224-23 in FIG. 8) when the down latch signal DLAT is enabled after the start of a down TSV open short test. The fourth fail signal generation circuit 224 may drive the TSV T41 through a PMOS transistor (224-22 in FIG. 8) when the up scan signal UPS is enabled after the start of an up TSV open short test. The fourth fail signal generation circuit 224 may latch the logic level of the internal node (ND224 in FIG. 8) that is connected to the TSV T41 driven through the PMOS transistor (224-22 in FIG. 8) when the up latch signal ULAT is enabled after the start of an up TSV open short test. The fourth fail signal generation circuit 224 may generate the fourth fail signal FAIL<4> based on the logic level of the internal node (ND224 in FIG. 8) that is connected to the TSV T41. The fourth fail signal generation circuit 224 may receive the high voltage VPP through the TSV T41 of the second voltage path after the start of a voltage monitoring operation. The fourth fail signal generation circuit 224 may output the high voltage VPP as the second transfer voltage TV2 after the start of a voltage monitoring operation.

The fail detection signal generation circuit 225 may generate the first to fourth fail detection signals FD<1:4> based on the first to fourth fail signals FAIL<1:4>. The fail detection signal generation circuit 225 may latch the first to fourth fail signals FAIL<1:4>. The fail detection signal generation circuit 225 may output the first to fourth fail signals FAIL<1:4> that have been latched as the first to fourth fail detection signals FD<1:4>.

FIG. 6 is a diagram illustrating a construction of the first fail signal generation circuit 221 according to an embodiment of the present disclosure. The first fail signal generation circuit 221 may include a first base driving circuit 221-1, a first storage circuit 221-2, and a first input and output circuit 221-3.

The first base driving circuit 221-1 may include an inverter 221-11, the PMOS transistor 221-12, and the NMOS transistor 221-13. The inverter 221-11 may output the up scan signal UPS by inverting the up scan signal UPS. The PMOS transistor 221-12 is connected between the internal voltage VINT and the node ND221 and may generate first base data BD1 having a logic high level by driving the node ND221 to the voltage level of the internal voltage VINT when the output signal of the inverter 221-11 is at a logic low level. The NMOS transistor 221-13 is connected between the node ND221 and the ground voltage VSS and may generate the first base data BD1 having a logic low level by driving the node ND221 to the voltage level of the ground voltage VSS when the down scan signal DNS is at a logic high level. The PMOS transistor 221-12 of the first base driving circuit 221-1 may be set to have a greater driving force than an NMOS transistor (511-13 in FIG. 11) of a first core driving circuit (511 in FIG. 11). Accordingly, the first base driving circuit 221-1 may drive the TSVs T11, T12, T13, T14, and T15 to the voltage level of the internal voltage VINT when a fail does not occur in the TSVs T11, T12, T13, T14, and T15 of the first signal path.

The first storage circuit 221-2 may include a first latch (1^{st} LATCH) 221-21, a second latch (2^{nd} LATCH) 221-22, and the AND gate 221-23.

The first latch 221-21 may generate first latch data LD1 having a logic high level when a power-up operation is terminated. The first latch 221-21 may latch the first base data BD1 when the down latch signal DLAT is enabled to a logic high level. The first latch 221-21 may output the first base data BD1 that have been latched as the first latch data LD1. The power-up operation may be set as an operation of the internal voltage VINT rising based on the voltage level of the power supply voltage VDD and being generated as a preset voltage level before the first to fourth core chips 130-1 to 130-4 start their operations.

The second latch 221-22 may generate second latch data LD2 having a logic high level when a power-up operation is terminated. The second latch 221-22 may latch the first base data BD1 when the up latch signal ULAT is enabled to a logic high level. The second latch 221-22 may output the first base data BD1 that have been latched as the second latch data LD2.

The AND gate 221-23 may generate the first fail signal FAIL<1> based on the logic levels of the first latch data LD1 and the second latch data LD2. The AND gate 221-23 may generate the first fail signal FAIL<1> having a logic high level when the first latch data LD1 are at a logic high level and the second latch data LD2 are at a logic high level. The AND gate 221-23 may generate the first fail signal FAIL<1> having a logic low level when at least any one of the first latch data LD1 and the second latch data LD2 is at a logic low level.

The first input and output circuit 221-3 may include a transmitter (TX) 221-31 and a receiver (RX) 221-32.

The transmitter 221-31 may be driven by receiving the internal voltage VINT. The transmitter 221-31 may output a first signal SIG1 to be output from the base chip 120 to the first to fourth core chips 130-1 to 130-4 to the TSV T11. The first signal SIG1 may be set as a signal including a command and data that control operations of the first to fourth core chips 130-1 to 130-4.

The receiver 221-32 may be driven by receiving the internal voltage VINT. The receiver 221-32 may output a second signal SIG2 that is received from the TSV T11 to the base chip 120. The second signal SIG2 may be set as a signal including data that are output from the first to fourth core chips 130-1 to 130-4.

The first input and output circuit 221-3 may output signals to be output from the base chip 120 to the first to fourth core chips 130-1 to 130-4 to the first to fourth core chips 130-1 to 130-4 through the TSV T11. The first input and output circuit 221-3 may receive signals to be output from the first to fourth core chips 130-1 to 130-4 to the base chip 120 through the TSV T11 and may output the signals to the base chip 120.

The second fail signal generation circuit 222, illustrated in FIG. 5, is electrically connected to the TSV T21 and generates the second fail signal FAIL<2> and is implemented with the same circuit as the first fail signal generation circuit 221, illustrated in FIG. 6, and performs the same operation as the first fail signal generation circuit 221. Thus a detailed description thereof is omitted.

FIG. 7 is a diagram illustrating a construction of the third fail signal generation circuit 223 according to an embodiment of the present disclosure. The third fail signal generation circuit 223 may include a first switch circuit 223-1, the third base driving circuit 223-2, and a third storage circuit 223-3.

The first switch circuit 223-1 may include transfer gates 223-11 and 223-12. The transfer gates 223-11 and 223-12 may be implemented with a PMOS transistor and an NMOS transistor that receive the high voltage VPP having a high voltage level through their gates and in which a voltage loss does not occur. When the scan enable signal SCE is enabled to the voltage level of the high voltage VPP and the inverse scan enable signal SCEB is disabled to the voltage level of the ground voltage VSS, the transfer gate 223-11 may connect the TSV T31 to the internal node ND223. When the scan enable signal SCE is disabled to the voltage level of the ground voltage VSS and the inverse scan enable signal SCEB is enabled to the voltage level of the high voltage VPP, the transfer gate 223-11 may cut off the connection between the TSV T31 and the internal node ND223. When the scan enable signal SCE is disabled to the voltage level of the ground voltage VSS and the inverse scan enable signal SCEB is enabled to the voltage level of the high voltage VPP, the transfer gate 223-12 may output the first transfer voltage TV1 by generating the first transfer voltage TV1 from the power supply voltage VDD that is input from the TSV T31. When the scan enable signal SCE is enabled to the voltage level of the high voltage VPP and the inverse scan enable signal SCEB is disabled to the voltage level of the ground voltage VSS, the transfer gate 223-12 might not output the power supply voltage VDD that is input from the TSV T31 as the first transfer voltage TV1. The first switch circuit 223-1 may connect the TSV T31 to the internal node ND223 when the scan enable signal SCE is enabled to the voltage level of the high voltage VPP. The first switch circuit 223-1 may cut off the connection between the TSV T31 and the internal node ND223 when the inverse scan enable signal SCEB is enabled to the voltage level of the high voltage VPP. The first switch circuit 223-1 may output the first transfer voltage TV1 by generating the first transfer voltage TV1 from the power supply voltage VDD that is input from the TSV T31 when the inverse scan enable signal SCEB is enabled to the voltage level of the high voltage VPP.

The third base driving circuit 223-2 may include an inverter 222-21, the PMOS transistor 223-22, and the NMOS transistor 223-23. The inverter 223-21 may output the up scan signal UPS by inverting the up scan signal UPS. The PMOS transistor 223-22 is connected between the internal voltage VINT and the node ND223 and may generate third base data BD3 having a logic high level by driving the node ND223 to the voltage level of the internal voltage VINT when the output signal of the inverter 223-21 is at a logic low level. The NMOS transistor 223-23 is connected between the node ND223 and the ground voltage VSS and may generate the third base data BD3 having a logic low level by driving the node ND223 to the voltage level of the ground voltage VSS when the down scan signal DNS is at a logic high level. The PMOS transistor 223-22 of the third base driving circuit 223-2 may be set to have a greater driving force than an NMOS transistor (513-23 in FIG. 12) of a third core driving circuit (513 in FIG. 12). Accordingly, the third base driving circuit 223-2 may drive the TSVs T31, T32, T33, T34, and T35 to the voltage level of the internal voltage VINT when a fail does not occur in the TSVs T31, T32, T33, T34, and T35 of the first voltage path. The third base driving circuit 223-2 may generate the third base data BD3 by driving the internal node ND223 that is connected to the TSV T31 through one of the PMOS transistor 223-22 and the NMOS transistor 223-23 based on the down scan signal DNS and the up scan signal UPS.

The third storage circuit 223-3 may include a fifth latch (5^{th} LATCH) 223-31, a sixth latch (6^{th} LATCH) 223-32, and an AND gate 223-33. The fifth latch 223-31 may generate fifth latch data LD5 having a logic high level when a power-up operation is terminated. The fifth latch 223-31 may latch the third base data BD3 when the down latch signal DLAT is enabled to a logic high level. The fifth latch 223-31 may output the third base data BD3 that have been latched as the fifth latch data LD5. The sixth latch 223-32 may generate sixth latch data LD6 having a logic high level when a power-up operation is terminated. The sixth latch 223-32 may latch the third base data BD3 when the up latch signal ULAT is enabled to a logic high level. The sixth latch 223-32 may output the third base data BD3 that have been latched as the sixth latch data LD6. The AND gate 223-33 may generate the third fail signal FAIL<3> based on the logic levels of the fifth latch data LD5 and the sixth latch data LD6. The AND gate 223-33 may generate the third fail signal FAIL<3> having a logic high level when the fifth latch data LD5 is at a logic high level and the sixth latch data LD6 is at a logic high level. The AND gate 223-33 may generate the third fail signal FAIL<3> having a logic low level when at least any one of the fifth latch data LD5 and the sixth latch data LD6 is at a logic low level. The third storage circuit 223-3 may latch the third base data BD3 based on the down latch signal DLAT and the up latch signal ULAT. The third storage circuit 223-3 may generate the third fail signal FAIL<3> from the third base data BD3 that have been latched.

FIG. 8 is a diagram illustrating a construction of the fourth fail signal generation circuit 224 according to an embodiment of the present disclosure. The fourth fail signal generation circuit 224 may include a second switch circuit 224-1, the fourth base driving circuit 224-2, and a fourth storage circuit 224-3.

The second switch circuit 224-1 may include transfer gates 224-11 and 224-12. The transfer gates 224-11 and 224-12 may be implemented with a PMOS transistor and an NMOS transistor that receive the high voltage VPP having a high voltage level through their gates and in which a voltage loss does not occur. When the scan enable signal SCE is enabled to the voltage level of the high voltage VPP and the inverse scan enable signal SCEB is disabled to the voltage level of the ground voltage VSS, the transfer gate 224-11 may connect the TSV T41 to the internal node ND224. When the scan enable signal SCE is disabled to the voltage level of the ground voltage VSS and the inverse scan enable signal SCEB is enabled to the voltage level of the high voltage VPP, the transfer gate 224-11 may cut off the connection between the TSV T41 and the internal node ND224. When the scan enable signal SCE is disabled to the voltage level of the ground voltage VSS and the inverse scan enable signal SCEB is enabled to the voltage level of the high voltage VPP, the transfer gate 224-12 may output the second transfer voltage TV2 by generating the second transfer voltage TV2 from the high voltage VPP that is input from the TSV T41. When the scan enable signal SCE is enabled to the voltage level of the high voltage VPP and the inverse scan enable signal SCEB is disabled to the voltage level of the ground voltage VSS, the transfer gate 224-12 might not output the high voltage VPP that is input from the TSV T41 as the second transfer voltage TV2. The second switch circuit 224-1 may connect the TSV T41 to the internal node ND224 when the scan enable signal SCE is enabled to the voltage level of the high voltage VPP. The second switch circuit 224-1 may cut off the connection between the TSV T41 and the internal node ND224 when the inverse scan enable signal SCEB is enabled to the voltage level of the high voltage VPP. The second switch circuit 224-1 may output the second transfer voltage TV2 by generating the second transfer voltage TV2 from the high voltage VPP that is input from the TSV T41 when the inverse scan enable signal SCEB is enabled to the voltage level of the high voltage VPP.

The fourth base driving circuit 224-2 may include an inverter 224-21, the PMOS transistor 224-22, and the NMOS transistor 224-23. The inverter 224-21 may output the up scan signal UPS by inverting the up scan signal UPS. The PMOS transistor 224-22 is connected between the internal voltage VINT and the node ND224 and may generate fourth base data BD4 having a logic high level by driving the node ND224 to the voltage level of the internal voltage VINT when the output signal of the inverter 224-21 is at a logic low level. The NMOS transistor 224-23 is connected between the node ND224 and the ground voltage VSS and may generate the fourth base data BD4 having a logic low level by driving the node ND224 to the voltage level of the ground voltage VSS when the down scan signal DNS is at a logic high level. The PMOS transistor 224-22 of the fourth base driving circuit 224-2 may be set to have a greater driving force than an NMOS transistor (514-23 in FIG. 13) of a fourth core driving circuit (514 in FIG. 13). Accordingly, the fourth base driving circuit 224-2 may drive the TSVs T41, T42, T43, T44, and T45 to the voltage level of the internal voltage VINT when a fail does not occur in the TSVs T41, T42, T43, T44, and T45 of the fourth signal path. The fourth base driving circuit 224-2 may generate the fourth base data BD4 by driving the internal node ND224 that is connected to the TSV T41 through one of the PMOS transistor 224-32 and the NMOS transistor 224-33 based on the down scan signal DNS and the up scan signal UPS.

The fourth storage circuit 224-3 may include a seventh latch (7^{th} LATCH) 224-31, an eighth latch (8^{th} LATCH) 224-32, and an AND gate 224-33. The seventh latch 224-31 may generate seventh latch data LD7 having a logic high level when a power-up operation is terminated. The seventh latch 224-31 may latch the fourth base data BD4 when the down latch signal DLAT is enabled to a logic high level. The seventh latch 224-31 may output the fourth base data BD4 that have been latched as the seventh latch data LD7. The eighth latch 224-32 may generate eighth latch data LD8 having a logic high level when a power-up operation is terminated. The eighth latch 224-32 may latch the fourth base data BD4 when the up latch signal ULAT is enabled to a logic high level. The eighth latch 224-32 may output the fourth base data BD4 that have been latched as the eighth latch data LD8. The AND gate 224-33 may generate the fourth fail signal FAIL<4> based on the logic level of the seventh latch data LD7 and the logic level of the eighth latch data LD8. The AND gate 224-33 may generate the fourth fail signal FAIL<4> having a logic high level when the seventh latch data LD7 is at a logic high level and the eighth latch data LD8 is at a logic high level. The AND gate 224-33 may generate the fourth fail signal FAIL<4> having a logic low level when at least any one of the seventh latch data LD7 and the eighth latch data LD8 is at a logic low level. The fourth storage circuit 224-3 may latch the fourth base data BD4 based on the down latch signal DLAT and the up latch signal ULAT. The fourth storage circuit 223-4 may generate the fourth fail signal FAIL<4> from the fourth base data BD4 that have been latched.

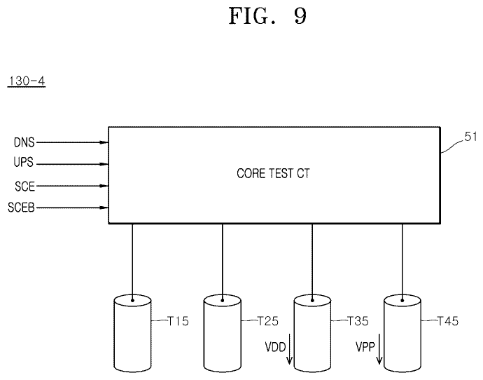

FIG. 9 is a block diagram illustrating a construction of the fourth core chip 130-4 according to an embodiment of the present disclosure. The fourth core chip 130-4 may include the TSVs T15, T25, T35, and T45 and the core test circuit 51.

The core test circuit 51 may receive the down scan signal DNS, the up scan signal UPS, the scan enable signal SCE, and the inverse scan enable signal SCEB from the base chip 120. The down scan signal DNS, the up scan signal UPS, the scan enable signal SCE, and the inverse scan enable signal SCEB may be input from the base chip 120 to the core test circuit 51 through TSVs separate from the TSVs T11, T12, T13, T14, T15, T21, T22, T23, T24, T25, T31, T32, T33, T34, T35, T41, T42, T43, T44, and T45.

The core test circuit 51 may be electrically connected to the TSVs T15, T25, T35, and T45. The core test circuit 51 may drive the TSVs T15, T25, T35, and T45 through any one of the PMOS transistor and the NMOS transistor after the start of a TSV open short test. The core test circuit 51 may drive the TSVs T14, T24, T34, and T44 through any one of the PMOS transistor and the NMOS transistor based on the down scan signal DNS and the up scan signal UPS after the start of a TSV open short test. The core test circuit 51 may drive the TSVs T15, T25, T35, and T45 with the internal voltage (VINT in FIG. 11) through the PMOS transistor when the down scan signal DNS is enabled after the start of a down TSV open short test of a TSV open short test. The core test circuit 51 may drive the TSVs T15, T25, T35, and T45 with the ground voltage (VSS in FIG. 11) through the NMOS transistor when the up scan signal UPS is enabled after the start of an up TSV open short test of a TSV open short test.

The core test circuit 51 may output the power supply voltage VDD through the TSV T31 of the first voltage path based on the scan enable signal SCE and the inverse scan enable signal SCEB after the start of a voltage monitoring operation. The core test circuit 51 may output the high voltage VPP through the TSV T41 of the second voltage path based on the scan enable signal SCE and the inverse scan enable signal SCEB after the start of a voltage monitoring operation. The core test circuit 51 may cut off the connection between the TSV T35 of the first voltage path and the third core driving circuit (513-2 in FIG. 12) based on the scan enable signal SCE and the inverse scan enable signal SCEB after the start of a voltage monitoring operation. The core test circuit 51 may cut off the connection between the TSV T45 of the second voltage path and the fourth core driving circuit (514-2 in FIG. 13) based on the scan enable signal SCE and the inverse scan enable signal SCEB after the start of a voltage monitoring operation.

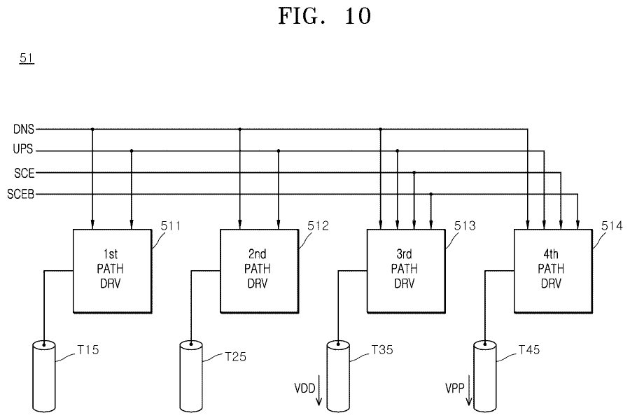

FIG. 10 is a block diagram illustrating a construction of the core test circuit 51 according to an embodiment of the present disclosure. The core test circuit 51 may include a first path driving circuit (1^{st} PATH DRV) 511, a second path driving circuit (2^{nd} PATH DRV) 512, a third path driving circuit (3^{rd} PATH DRV) 513, and a fourth path driving circuit (4^{th} PATH DRV) 514.

The first path driving circuit 511 may be electrically connected to the TSV T15 of the first signal path. The first path driving circuit 511 may drive the TSV T15 based on the down scan signal DNS and the up scan signal UPS. The first path driving circuit 511 may drive the TSV T15 through a PMOS transistor (511-12 in FIG. 11) when the down scan signal DNS is enabled. The first path driving circuit 511 may drive the TSV T15 through the NMOS transistor (511-13 in FIG. 11) when the up scan signal UPS is enabled.

The second path driving circuit 512 may be electrically connected to the TSV T25 of the second signal path. The second path driving circuit 512 may drive the TSV T25 based on the down scan signal DNS and the up scan signal UPS. The second path driving circuit 512 may drive the TSV T25 through a PMOS transistor (not illustrated) when the down scan signal DNS is enabled. The second path driving circuit 512 may drive the TSV T25 through an NMOS transistor (not illustrated) when the up scan signal UPS is enabled.

The third path driving circuit 513 may be electrically connected to the TSV T35 of the first voltage path. The third path driving circuit 513 may drive the TSV T35 based on the down scan signal DNS and the up scan signal UPS. The third path driving circuit 513 may drive the TSV T35 through a PMOS transistor (513-22 in FIG. 12) when the down scan signal DNS is enabled. The third path driving circuit 513 may drive the TSV T35 through the NMOS transistor (513-23 in FIG. 12) when the up scan signal UPS is enabled.

The third path driving circuit 513 may output the power supply voltage VDD through the TSV T35 based on the scan enable signal SCE and the inverse scan enable signal SCEB. The third path driving circuit 513 may cut off the connection between the TSV T35 and the third core driving circuit (513-2 in FIG. 12) based on the scan enable signal SCE and the inverse scan enable signal SCEB.

The fourth path driving circuit 514 may be electrically connected to the TSV T45 of the second voltage path. The fourth path driving circuit 514 may drive the TSV T45 based on the down scan signal DNS and the up scan signal UPS. The fourth path driving circuit 514 may drive the TSV T45 through a PMOS transistor (514-22 in FIG. 13) when the down scan signal DNS is enabled. The fourth path driving circuit 514 may drive the TSV T45 through the NMOS transistor (514-23 in FIG. 13) when the up scan signal UPS is enabled.

The fourth path driving circuit 514 may output the high voltage VPP through the TSV T45 based on the scan enable signal SCE and the inverse scan enable signal SCEB. The fourth path driving circuit 514 may cut off the connection between the TSV T45 and the fourth core driving circuit (514-2 in FIG. 13) based on the scan enable signal SCE and the inverse scan enable signal SCEB.

FIG. 11 is a diagram illustrating a construction of the first path driving circuit 511 according to an embodiment of the present disclosure. The first path driving circuit 511 may include a first core driving circuit 511-1 and a third input and output circuit 511-2.

The first core driving circuit 511-1 may include an inverter 511-11, a PMOS transistor 511-12, and the NMOS transistor 511-13. The inverter 511-11 may output the down scan signal DNS by inverting the down scan signal DNS. The PMOS transistor 511-12 is connected between the internal voltage VINT and a node ND511 and may generate first core data CD1 having a logic high level by driving the node ND511 to the voltage level of the internal voltage VINT when the output signal of the inverter 511-11 is at a logic low level. The NMOS transistor 511-13 is connected between the node ND511 and the ground voltage VSS and may generate the first core data CD1 having a logic low level by driving the node ND511 to the voltage level of the ground voltage VSS when the up scan signal UPS is at a logic high level. The PMOS transistor 511-12 of the first core driving circuit 511-1 may be set to have a greater driving force than the NMOS transistor (221-13 in FIG. 6) of the first fail signal generation circuit 221. Accordingly, the first core driving circuit 511-1 may drive the TSVs T11, T12, T13, T14, and T15 to the voltage level of the internal voltage VINT when a fail does not occur in the TSVs T11, T12, T13, T14, and T15 of the first signal path.

The third input and output circuit 511-2 may include a transmitter (TX) 511-21 and a receiver (RX) 511-22. The transmitter 511-21 may be driven by receiving the internal voltage VINT. The transmitter 511-21 may output a third signal SIG3 to be output from the fourth core chip 130-4 to the base chip 120 to the TSV T15. The third signal SIG3 may be set as a signal including data stored therein.

The receiver 511-22 may be driven by receiving the internal voltage VINT. The receiver 511-22 may output a fourth signal SIG4 that is received from the TSV T15 to the fourth core chip 130-4. The fourth signal SIG4 may be set as a signal including a command and data that control operations of the first to fourth core chips 130-1 to 130-4.

The third input and output circuit 511-2 may output a signal to be output from the fourth core chip 130-4 to the base chip 120 to the base chip 120 through the TSV T15. The third input and output circuit 511-2 may receive a signal to be output from the base chip 120 to the fourth core chip 130-4 through the TSV T15 and may output the signal to the fourth core chip 130-4.

The second path driving circuit 512, illustrated in FIG. 10, is electrically connected to the TSV T25 and drives the TSV T25 and is implemented with the same circuit as the first path driving circuit 511, illustrated in FIG. 11, and performs the same operation as the first path driving circuit 511. Thus, a detailed description thereof is omitted.

FIG. 12 is a diagram illustrating a construction of the third path driving circuit 513 according to an embodiment of the present disclosure. The third path driving circuit 513 may include a third switch circuit 513-1 and the third core driving circuit 513-2.

The third switch circuit 513-1 may include transfer gates 513-11 and 513-12. The transfer gates 513-11 and 513-12 may be implemented with a PMOS transistor and an NMOS transistor that receive the high voltage VPP having a high voltage level through their gates and in which a voltage loss does not occur. When the scan enable signal SCE is enabled to the voltage level of the high voltage VPP and the inverse scan enable signal SCEB is disabled to the voltage level of the ground voltage VSS, the transfer gate 513-11 may connect the TSV T35 to an internal node ND513. When the scan enable signal SCE is disabled to the voltage level of the ground voltage VSS and the inverse scan enable signal SCEB is enabled to the voltage level of the high voltage VPP, the transfer gate 513-11 may cut off the connection between the TSV T35 and the internal node ND513. When the scan enable signal SCE is disabled to the voltage level of the ground voltage VSS and the inverse scan enable signal SCEB is enabled to the voltage level of the high voltage VPP, the transfer gate 513-12 may output the power supply voltage VDD through the TSV T35. When the scan enable signal SCE is enabled to the voltage level of the high voltage VPP and the inverse scan enable signal SCEB is disabled to the voltage level of the ground voltage VSS, the transfer gate 513-12 might not output the power supply voltage VDD to the TSV T35. The third switch circuit 513-1 may connect the TSV T35 to the internal node ND513 when the scan enable signal SCE is enabled to the voltage level of the high voltage VPP. The third switch circuit 513-1 may cut off the connection between the TSV T35 and the internal node ND513 when the inverse scan enable signal SCEB is enabled to the voltage level of the high voltage VPP. The third switch circuit 513-1 may output the power supply voltage VDD through the TSV T35 when the inverse scan enable signal SCEB is enabled to the voltage level of the high voltage VPP.

The third core driving circuit 513-2 may include an inverter 513-21, the PMOS transistor 513-22, and the NMOS transistor 513-23. The inverter 513-21 may output the down scan signal DNS by inverting the down scan signal DNS. The PMOS transistor 513-22 is connected between the internal voltage VINT and the node ND513 and may generate third core data CD3 having a logic high level by driving the node ND513 to the voltage level of the internal voltage VINT when the output signal of the inverter 513-21 is at a logic low level. The NMOS transistor 513-23 is connected between the node ND513 and the ground voltage VSS and may generate the third core data CD3 having a logic low level by driving the node ND513 to the voltage level of the ground voltage VSS when the up scan signal UPS is at a logic high level. The PMOS transistor 513-22 of the third core driving circuit 513-2 may be set to have a greater driving force than the NMOS transistor (223-23 in FIG. 7) of the third base driving circuit (223-2 in FIG. 7). Accordingly, the third core driving circuit 513-2 may drive the TSVs T31, T32, T33, T34, and T35 to the voltage level of the internal voltage VINT when a fail does not occur in the TSVs T31, T32, T33, T34, and T35 of the first voltage path. The third core driving circuit 513-2 may generate the third core data CD3 by driving the internal node ND513 that is connected to the TSV T35 through any one of the PMOS transistor 513-22 and the NMOS transistor 513-23 based on the down scan signal DNS and the up scan signal UPS.

FIG. 13 is a diagram illustrating a construction of the fourth path driving circuit 514 according to an embodiment of the present disclosure. The fourth path driving circuit 514 may include a fourth switch circuit 514-1 and the fourth core driving circuit 514-2.

The fourth switch circuit 514-1 may include transfer gates 514-11 and 514-12. The transfer gates 514-11 and 514-12 may be implemented with a PMOS transistor and an NMOS transistor that receive the high voltage VPP having a high voltage level through their gates and in which a voltage loss does not occur. When the scan enable signal SCE is enabled to the voltage level of the high voltage VPP and the inverse scan enable signal SCEB is disabled to the voltage level of the ground voltage VSS, the transfer gate 514-11 may connect the TSV T45 to an internal node ND514. When the scan enable signal SCE is disabled to the voltage level of the ground voltage VSS and the inverse scan enable signal SCEB is enabled to the voltage level of the high voltage VPP, the transfer gate 514-11 may cut off the connection between the TSV T45 and the internal node ND514. When the scan enable signal SCE is disabled to the voltage level of the ground voltage VSS and the inverse scan enable signal SCEB is enabled to the voltage level of the high voltage VPP, the transfer gate 514-12 may output the high voltage VPP through the TSV T45. When the scan enable signal SCE is enabled to the voltage level of the high voltage VPP and the inverse scan enable signal SCEB is disabled to the voltage level of the ground voltage VSS, the transfer gate 514-12 might not output the high voltage VPP to the TSV T45. The fourth switch circuit 514-1 may connect the TSV T45 to the internal node ND514 when the scan enable signal SCE is enabled to the voltage level of the high voltage VPP. The fourth switch circuit 514-1 may cut off the connection between the TSV T45 and the internal node ND514 when the inverse scan enable signal SCEB is enabled to the voltage level of the high voltage VPP. The fourth switch circuit 514-1 may output the high voltage VPP through the TSV T45 when the inverse scan enable signal SCEB is enabled to the voltage level of the high voltage VPP.

The fourth core driving circuit 514-2 may include an inverter 514-21, the PMOS transistor 514-22, and the NMOS transistor 514-23. The inverter 514-21 may output the down scan signal DNS by inverting the down scan signal DNS. The PMOS transistor 514-22 is connected between the internal voltage VINT and the node ND514 and may generate fourth core data CD4 having a logic high level by driving the node ND514 to the voltage level of the internal voltage VINT when the output signal of the inverter 514-21 is at a logic low level. The NMOS transistor 514-23 is connected between the node ND514 and the ground voltage VSS and may generate the fourth core data CD4 having a logic low level by driving the node ND514 to the voltage level of the ground voltage VSS when the up scan signal UPS is at a logic high level. The PMOS transistor 514-22 of the fourth core driving circuit 514-2 may be set to have a greater driving force than the NMOS transistor (224-23 in FIG. 7) of the third base driving circuit (224-2 in FIG. 8). Accordingly, the fourth core driving circuit 514-2 may drive the TSVs T41, T42, T43, T44, and T45 to the voltage level of the internal voltage VINT when a fail does not occur in the TSVs T41, T42, T43, T44, and T45 of the second voltage path. The fourth core driving circuit 514-2 may generate the fourth core data CD4 by driving the internal node ND514 that is connected to the TSV T45 through one of the PMOS transistor 514-22 and the NMOS transistor 514-23 based on the down scan signal DNS and the up scan signal UPS.

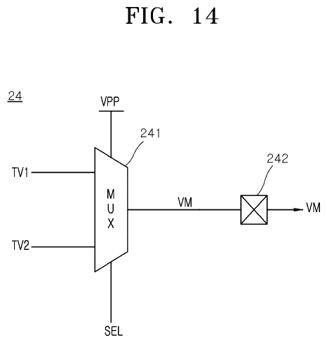

FIG. 14 is a block diagram illustrating a construction of the voltage monitoring circuit 24 according to an embodiment of the present disclosure. The voltage monitoring circuit 24 may include a selection transfer circuit (MUX) 241 and a pad 242.

The selection transfer circuit 241 may be driven by receiving the high voltage VPP. The selection transfer circuit 241 may be implemented with a multiplexer that receives the high voltage VPP and in which a voltage loss does not occur. The selection transfer circuit 241 may generate the monitoring voltage VM from any one of the first transfer voltage TV1 and the second transfer voltage TV2 based on a selection signal SEL. The selection transfer circuit 241 may output the first transfer voltage TV1 as the monitoring voltage VM when the selection signal SEL is at a logic low level. The selection transfer circuit 241 may output the second transfer voltage TV2 as the monitoring voltage VM when the selection signal SEL is at a logic high level. The selection signal SEL may be set as a signal that is generated at a logic low level in order to monitor the power supply voltage VDD after the start of a voltage monitoring operation. The selection signal SEL may be set as a signal that is generated at a logic high level in order to monitor the high voltage VPP after the start of a voltage monitoring operation.

The pad 242 may receive the monitoring voltage VM. The pad 242 may output the received monitoring voltage VM to an external device, for example, the processor 19. The pad 242 may be set as a common pad.

The voltage monitoring circuit 24 may detect the voltage level of the monitoring voltage VM that is generated from the power supply voltage VDD that is input through the first voltage path. The voltage monitoring circuit 24 may detect the voltage level of the monitoring voltage VM that is generated from the high voltage VPP that is input through the second voltage path.

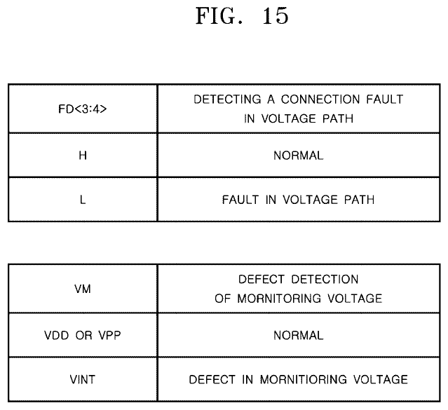

FIG. 15 is a table for describing an operation that detects a connection fail of a voltage path and a fail of a monitoring voltage in the memory device according to an embodiment of the present disclosure. An operation that detects a connection fail of the voltage paths and then detecting a fail of the monitoring voltage is described as an example as follows with reference to FIG. 15.

First, an operation that detects a connection fail of the voltage paths (DETECTING A CONNECTION FAULT IN VOLTAGE PATH) is described as follows.

After the start of a TSV open short test, when a fail does not occur in the first voltage path and the second voltage path (NORMAL), the third fail detection signal FD<3> and the fourth fail detection signal FD<4> are generated at a logic high level H because the first voltage path and the second voltage path are driven to the voltage level of the internal voltage VINT. When the third fail detection signal FD<3> and the fourth fail detection signal FD<4> are generated at a logic high level H, the base chip 120 may detect that a fail does not occur in the first voltage path and the second voltage path.

After the start of a TSV open short test, when a fail occurs in the first voltage path and the second voltage path (FAULT IN VOLTAGE PATH), the third fail detection signal FD<3> and the fourth fail detection signal FD<4> are generated at a logic low level L because the first voltage path and the second voltage path are not driven to the voltage level of the internal voltage VINT. When the third fail detection signal FD<3> and the fourth fail detection signal FD<4> are generated at a logic low level L, the base chip 120 may detect that a fail occurs in the first voltage path and the second voltage path.

An operation that detects a connection fail of the first signal path and the second signal path is the same as the operation that detects a connection fail of the first voltage path and the second voltage path, and thus, a detailed description thereof is omitted.

An operation that detects a fail of the monitoring voltage is described as an example as follows.

After the start of a monitoring operation, when the power supply voltage VDD that is used in the first to fourth core chips 130-1 to 130-4 is normal (NORMAL), the monitoring voltage VM that is generated from the first voltage path is generated at the voltage level of the power supply voltage VDD. When the monitoring voltage VM is generated at the voltage level of the power supply voltage VDD, the base chip 120 may detect that a fail does not occur in the power supply voltage VDD that is used in the first to fourth core chips 130-1 to 130-4.

After the start of a monitoring operation, when the high voltage VPP that is used in the first to fourth core chips 130-1 to 130-4 is normal (NORMAL), the monitoring voltage VM that is generated from the second voltage path is generated at the voltage level of the high voltage VPP. When the monitoring voltage VM is generated at the voltage level of the high voltage VPP, the base chip 120 may detect that a fail does not occur in the high voltage VPP that is used in the first to fourth core chips 130-1 to 130-4.

After the start of a monitoring operation, when a fail occurs in the power supply voltage VDD that is used in the first to fourth core chips 130-1 to 130-4 (DEFECT IN MORNITIORING VOLTAGE), the monitoring voltage VM that is generated from the first voltage path is generated at the voltage level of the internal voltage VINT. When the monitoring voltage VM is generated at the voltage level of the internal voltage VINT, the base chip 120 may detect that a fail occurs in the power supply voltage VDD that is used in the first to fourth core chips 130-1 to 130-4.

After the start of a monitoring operation, when a fail occurs in the high voltage VPP that is used in the first to fourth core chips 130-1 to 130-4 (DEFECT IN MORNITIORING VOLTAGE), the monitoring voltage VM that is generated from the second voltage path is generated at the voltage level of the internal voltage VINT. When the monitoring voltage VM is generated at the voltage level of the internal voltage VINT, the base chip 120 may detect that a fail occurs in the high voltage VPP that is used in the first to fourth core chips 130-1 to 130-4.

As described above, the memory device 17 according to an embodiment of the present disclosure can detect a connection fail of a signal path and a voltage path by detecting the logic level of an internal node that is connected to the signal path and the voltage path. The memory device 17 can protect elements included in a driving circuit by cutting off the connection between a voltage path that outputs the high voltage and a driving circuit that drives the voltage path after the start of a TSV open short test. The memory device 17 can detect a connection fail of a voltage path and a fail of the monitoring voltage by detecting a connection fail of the voltage path after the start of a TSV open short test and monitoring the voltage level of the monitoring voltage that is output to the voltage path after the start of a voltage monitoring operation.

The embodiments of the present disclosure have been described so far. A person having ordinary knowledge in the art to which the present invention pertains will understand that the present invention may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A memory device comprising:
a base chip; and
a core chip that is stacked over the base chip and connected through a voltage path,
wherein the base chip and the core chip drive the voltage path with an internal voltage after a start of a TSV open short test and detect a connection fail of the voltage path based on a logic level at which the voltage path is driven,
wherein the base chip cuts off a connection between the voltage path and a base driving circuit after a start of a voltage monitoring operation,
wherein the core chip cuts off a connection between the voltage path and a core driving circuit after the start of the voltage monitoring operation, and
wherein the base chip detects a voltage level of a monitoring voltage, generated during the voltage monitoring operation, that is used in the core chip through the voltage path.

2. The memory device of claim 1,
wherein the base chip drives the voltage path through any one of a first PMOS transistor and a first NMOS transistor that is connected to the voltage path after the start of the TSV open short test, and
wherein the core chip drives the voltage path through any one of a second PMOS transistor and a second NMOS transistor that is connected to the voltage path after the start of the TSV open short test.

3. The memory device of claim 1, wherein the monitoring voltage is set as a voltage having a higher voltage level than the internal voltage.

4. The memory device of claim 1, wherein the base chip comprises:
a test control circuit configured to generate a down scan signal, an up scan signal, a down latch signal, an up latch signal, a scan enable signal, and an inverse scan enable signal from a down enable signal and an up enable signal that perform the TSV open short test;
a base test circuit configured to control the connection between the voltage path and the base driving circuit based on the scan enable signal and the inverse scan enable signal, configured to drive the voltage path based on the down scan signal and the up scan signal, configured to generate a fail detection signal based on a logic level of the voltage path, and configured to output a transfer voltage that is transferred through the voltage path;
a fail detection circuit configured to detect a connection fail of the voltage path based on the fail detection signal; and
a voltage monitoring circuit configured to generate the monitoring voltage from the transfer voltage and configured to detect the voltage level of the monitoring voltage.

5. The memory device of claim 4, wherein the test control circuit comprises:
a scan control circuit configured to generate the down scan signal and the up scan signal when the down enable signal and the up enable signal are enabled and configured to generate the down latch signal the up latch signal by delaying the down scan signal and the up scan signal;
an enable signal generation circuit configured to receive the internal voltage and configured to generate an enable signal that is driven with the internal voltage when any one of the down scan signal and the up scan signal is enabled; and
a level shifting circuit configured to receive a high voltage and configured to generate the scan enable signal and the inverse scan enable signal having a voltage level of the high voltage by converting a logic level of the enable signal.

6. The memory device of claim 4, wherein the base test circuit comprises:
a fail signal generation circuit configured to control the connection between the voltage path and the base driving circuit based on the scan enable signal and the inverse scan enable signal, configured to drive the voltage path through the base driving circuit based on the down scan signal and the up scan signal, configured to generate a fail signal based on a logic level of a first internal node that is connected to the voltage path when the down latch signal and the up latch signal are generated, and configured to output the transfer voltage that is transferred through the voltage path; and
a fail detection signal generation circuit configured to generate the fail detection signal by latching the fail signal.

7. The memory device of claim 4, wherein the voltage monitoring circuit comprises:
a selection transfer circuit configured to generate the monitoring voltage from the transfer voltage based on a selection signal; and
a pad configured to receive the monitoring voltage and configured to output the monitoring voltage to a device external to the memory device.

8. The memory device of claim 6, wherein the fail signal generation circuit comprises:
a first switch circuit configured to connect the voltage path to the first internal node when the scan enable signal is enabled, configured to cut off the connection between the voltage path and the first internal node when the inverse scan enable signal is enabled, and configured to generate the transfer voltage from the voltage path when the inverse scan enable signal is enabled;
a base driving circuit configured to drive base data by driving the first internal node through one of a first PMOS transistor and a first NMOS transistor based on the down scan signal and the up scan signal; and
a storage circuit configured to latch the base data based on the down latch signal and the up latch signal and configured to generate the fail signal from the latched base data.

9. The memory device of claim 1, wherein the core chip comprises a path driving circuit configured to control a connection between the voltage path and a core driving circuit based on a scan enable signal and an inverse scan enable signal, configured to drive the voltage path through the core driving circuit based on a down scan signal and an up scan signal, and configured to output a high voltage through the voltage path.

10. The memory device of claim 9, wherein the path driving circuit comprises:
a second switch circuit configured to connect the voltage path and a second internal node when the scan enable signal is enabled, configured to cut off the connection between the voltage path and the second internal node when the inverse scan enable signal is enabled, and configured to output the high voltage to the voltage path when the inverse scan enable signal is enabled; and
a core driving circuit configured to drive core data by driving the second internal node through any one of a second PMOS transistor and a second NMOS transistor based on the down scan signal and the up scan signal.

11. A memory device comprises:
a base chip; and
a core chip that is stacked over the base chip and connected through first and second voltage paths,
wherein the base chip and the core chip drive the first and second voltage paths with an internal voltage after a start of a TSV open short test and detect a connection fail of the first and second voltage paths based on logic levels at which the first and second voltage paths are driven, and
wherein the base chip detects a voltage level of a monitoring voltage that is generated from any one of a power supply voltage that is received through the first voltage path and a high voltage that is received through the second voltage path after a start of a voltage monitoring operation.

12. The memory device of claim 11,
wherein the power supply voltage is set as a voltage having a higher voltage level than the internal voltage,
wherein the high voltage is a voltage having a higher voltage level than the power supply voltage, and
wherein the power supply voltage and the high voltage are each set as a voltage that is used within the core chip.

13. The memory device of claim 11, wherein the base chip comprises:
a test control circuit configured to generate a down scan signal, an up scan signal, a down latch signal, an up latch signal, a scan enable signal, and an inverse scan enable signal from a down enable signal and an up enable signal that perform the TSV open short test;
a base test circuit configured to drive the first voltage path and the second voltage path based on the scan enable signal and the inverse scan enable signal, configured to generate first and second fail detection signals based on logic levels of the first and second voltage paths, and configured to output a first transfer voltage that is generated from the power supply voltage through the first voltage path and a second transfer voltage that is generated from the high voltage through the second voltage path;
a fail detection circuit configured to detect the connection fail of the first and second voltage paths based on the first and second fail detection signals; and
a voltage monitoring circuit configured to generate the monitoring voltage from any one of the first and second transfer voltages and configured to detect the voltage level of the monitoring voltage.

14. The memory device of claim 13, wherein the test control circuit comprises:
a scan control circuit configured to generate the down scan signal and the up scan signal when the down enable signal and the up enable signal are enabled and configured to generate the down latch signal the up latch signal by delaying the down scan signal and the up scan signal;
an enable signal generation circuit configured to receive the internal voltage and configured to generate an enable signal that is driven with the internal voltage when any one of the down scan signal and the up scan signal is enabled; and
a level shifting circuit configured to receive the high voltage and configured to generate the scan enable signal and the inverse scan enable signal having a voltage level of the high voltage by converting a logic level of the enable signal.

15. The memory device of claim 13, wherein the base test circuit comprises:
a first fail signal generation circuit configured to control a connection between the first voltage path and a first base driving circuit based on the scan enable signal and the inverse scan enable signal, configured to drive the first voltage path through the first base driving circuit based on the down scan signal and the up scan signal, configured to generate a first fail signal based on the logic level of the first voltage path, and configured to output the first transfer voltage that is transferred through the first voltage path;
a second fail signal generation circuit configured to control a connection between the second voltage path and a second base driving circuit based on the scan enable signal and the inverse scan enable signal, configured to drive the second voltage path through the second base driving circuit based on the down scan signal and the up scan signal, configured to generate a second fail signal based on the logic level of the second voltage path, and configured to output the second transfer voltage that is transferred through the second voltage path; and
a fail detection signal generation circuit configured to generate the first and second fail detection signals by latching the first and second fail signals.

16. The memory device of claim 15, wherein the first fail signal generation circuit comprises:
a first switch circuit configured to connect the first voltage path and a first internal node when the scan enable signal is enabled, configured to cut off the connection between the first voltage path and the first internal node when the inverse scan enable signal is enabled, and configured to generate the first transfer voltage from the first voltage path when the inverse scan enable signal is enabled;
the first base driving circuit configured to drive first base data by driving the first internal node through one of a first PMOS transistor and a first NMOS transistor based on the down scan signal and the up scan signal; and
a first storage circuit configured to latch the first base data based on the down latch signal and the up latch signal and configured to generate the first fail signal from the first base data that have been latched.

17. The memory device of claim 15, wherein the second fail signal generation circuit comprises:
a second switch circuit configured to connect the second voltage path and a second internal node when the scan enable signal is enabled, configured to cut off the connection between the second voltage path and the second internal node when the inverse scan enable signal is enabled, and configured to generate the second transfer voltage from the second voltage path when the inverse scan enable signal is enabled;
the second base driving circuit configured to drive second base data by driving the second internal node through one of a second PMOS transistor and a second NMOS transistor based on the down scan signal and the up scan signal; and
a second storage circuit configured to latch the second base data based on the down latch signal and the up latch signal and configured to generate the second fail signal from the second base data that have been latched.

18. The memory device of claim 13, wherein the voltage monitoring circuit comprises:
a selection transfer circuit configured to generate the monitoring voltage from any one of the first and second transfer voltages based on a selection signal; and
a pad configured to receive the monitoring voltage and configured to output the monitoring voltage to a device external to the memory device.

19. The memory device of claim 11, wherein the core chip comprises a core test circuit configured to control a connection between the first voltage path and a first core driving circuit based on a scan enable signal and an inverse scan enable signal, configured to control a connection between the second voltage path and a second core driving circuit based on the scan enable signal and the inverse scan enable signal, configured to drive the first voltage path and the second voltage path based on a down scan signal and an up scan signal, configured to output the power supply voltage to the first voltage path, and configured to output the high voltage to the second voltage path.

20. The memory device of claim 19, wherein the core test circuit comprises:
a first path driving circuit configured to drive the first voltage path based on the down scan signal and the up scan signal and configured to output the power supply voltage to the first voltage path; and
a second path driving circuit configured to drive the second voltage path based on the down scan signal and the up scan signal and configured to output the high voltage to the second voltage path.

21. The memory device of claim 20, wherein the first path driving circuit comprises:
a third switch circuit configured to connect the first voltage path and a third internal node when the scan enable signal is enabled, configured to cut off the connection between the first voltage path and the third internal node when the inverse scan enable signal is enabled, and configured to output the power supply voltage through the first voltage path when the inverse scan enable signal is enabled; and
the first core driving circuit configured to drive first core data by driving the third internal node through one of a third PMOS transistor and a third NMOS transistor based on the down scan signal and the up scan signal.

22. The memory device of claim 20, wherein the second path driving circuit comprises:
a fourth switch circuit configured to connect the second voltage path and a fourth internal node when the scan enable signal is enabled, configured to cut off the connection between the second voltage path and the fourth internal node when the inverse scan enable signal is enabled, and configured to output the high voltage through the second voltage path when the inverse scan enable signal is enabled; and
the second core driving circuit configured to drive second core data by driving the fourth internal node through one of a fourth PMOS transistor and a fourth NMOS transistor based on the down scan signal and the up scan signal.

23. A memory device comprising:
a base chip; and
a core chip that is stacked over the base chip and connected through a signal path and a voltage path,
wherein the base chip and the core chip drive the signal path and the voltage path after a start of a TSV open short test and detect a connection fail of the signal path and the voltage path based on logic levels at which the signal path and the voltage path are driven,
wherein the base chip cuts off a connection between the voltage path and a base driving circuit after a start of a voltage monitoring operation,
wherein the core chip cuts off the connection between the voltage path and the path driving circuit after the start of the voltage monitoring operation, and
wherein the base chip detects a voltage level of a high voltage that is used in the core chip through the voltage path after the start of the voltage monitoring operation.

24. An integrated circuit comprising:
a semiconductor device configured to drive first and second voltage paths with an internal voltage after a start of a TSV open short test, configured to control a connection between the first and second voltage paths and first and second base driving circuits, configured to detect a connection fail of the first and second voltage paths based on logic levels at which the first and second voltage paths are driven, and configured to detect a voltage level of a monitoring voltage that is generated from any one of a power supply voltage that is received through the first voltage path and a high voltage that is received through the second voltage path after a start of a voltage monitoring operation.

25. The integrated circuit of claim 24,
wherein the power supply voltage is set as a voltage having a higher voltage level than the internal voltage,
wherein the high voltage is a voltage having a higher voltage level than the power supply voltage,
wherein the internal voltage is a voltage that is used within the semiconductor device, and
wherein the power supply voltage and the high voltage are set as voltages that are used outside the semiconductor device.

26. The integrated circuit of claim 24, wherein the semiconductor device comprises:
a test control circuit configured to generate a down scan signal, an up scan signal, a down latch signal, an up latch signal, a scan enable signal, and an inverse scan enable signal from a down enable signal and an up enable signal that perform the TSV open short test;
a base test circuit configured to drive the first voltage path and the second voltage path based on the scan enable signal and the inverse scan enable signal, configured to generate first and second fail detection signals based on logic levels of the first and second voltage paths, and configured to output a first transfer voltage that is generated from the power supply voltage through the first voltage path and a second transfer voltage that is generated from the high voltage through the second voltage path;
a fail detection circuit configured to detect the connection fail of the first and second voltage paths based on the first and second fail detection signals; and
a voltage monitoring circuit configured to generate the monitoring voltage from any one of the first and second transfer voltages and configured to detect the voltage level of the monitoring voltage.

27. The integrated circuit of claim 26, wherein the test control circuit comprises:
a scan control circuit configured to generate the down scan signal and the up scan signal when the down enable signal and the up enable signal are enabled and configured to generate the down latch signal the up latch signal by delaying the down scan signal and the up scan signal;
an enable signal generation circuit configured to receive the internal voltage and configured to generate an enable signal that is driven with the internal voltage when any one of the down scan signal and the up scan signal is enabled; and
a level shifting circuit configured to receive the high voltage and configured to generate the scan enable signal and the inverse scan enable signal having a voltage level of the high voltage by converting a logic level of the enable signal.

28. The integrated circuit of claim 26, wherein the base test circuit comprises:
a first fail signal generation circuit configured to control a connection between the first voltage path and the first base driving circuit based on the scan enable signal and the inverse scan enable signal, configured to drive the first voltage path through the first base driving circuit based on the down scan signal and the up scan signal, configured to generate a first fail signal based on the logic level of the first voltage path, and configured to output the first transfer voltage that is transferred through the first voltage path;
a second fail signal generation circuit configured to control a connection between the second voltage path and a second base driving circuit based on the scan enable signal and the inverse scan enable signal, configured to drive the second voltage path through the second base driving circuit based on the down scan signal and the up scan signal, configured to generate a second fail signal based on a logic level of the second voltage path, and configured to output the second transfer voltage that is transferred through the second voltage path; and
a fail detection signal generation circuit configured to generate the first and second fail detection signals by latching the first and second fail signals.

29. The integrated circuit of claim 28, wherein the first fail signal generation circuit comprises:
a first switch circuit configured to connect the first voltage path and a first internal node when the scan enable signal is enabled, configured to cut off the connection between the first voltage path and the first internal node when the inverse scan enable signal is enabled, and configured to generate the first transfer voltage from the first voltage path when the inverse scan enable signal is enabled;
the first base driving circuit configured to drive first base data by driving the first internal node through one of a first PMOS transistor and a first NMOS transistor based on the down scan signal and the up scan signal; and
a first storage circuit configured to latch the first base data based on the down latch signal and the up latch signal and configured to generate the first fail signal from the first base data that have been latched.

30. The integrated circuit of claim 28, wherein the second fail signal generation circuit comprises:
a second switch circuit configured to connect the second voltage path and a second internal node when the scan enable signal is enabled, configured to cut off the connection between the second voltage path and the second internal node when the inverse scan enable signal is enabled, and configured to generate the second transfer voltage from the second voltage path when the inverse scan enable signal is enabled;
the second base driving circuit configured to drive second base data by driving the second internal node through one of a second PMOS transistor and a second NMOS transistor based on the down scan signal and the up scan signal; and
a second storage circuit configured to latch the second base data based on the down latch signal and the up latch signal and configured to generate the second fail signal from the second base data that have been latched.

31. The integrated circuit of claim 26, wherein the voltage monitoring circuit comprises:
a selection transfer circuit configured to generate the monitoring voltage from any one of the first and second transfer voltages based on a selection signal; and
a pad configured to receive the monitoring voltage and configured to output the monitoring voltage to a device external to the memory device.
